(19) United States
(12) Patent Application Publication
(10) Pub. No.: US 2024/0332361 A1
(43) Pub. Date: Oct. 3, 2024

(54) SEMICONDUCTOR DECIVE AND PRODUCTION METHOD THEREFOR

(71) Applicant: TOYODA GOSEI CO., LTD., Kiyosu-shi (JP)

(72) Inventor: Kimiyasu IDE, Kiyosu-shi (JP)

(21) Appl. No.: 18/602,855

(22) Filed: Mar. 12, 2024

(30) Foreign Application Priority Data
Mar. 29, 2023 (JP) 2023-053329

(51) Int. Cl. H01L 29/08; H01L 21/306; H01L 29/20; H01L 29/66; H01L 29/778

(52) U.S. Cl. CPC H01L 29/0891; H01L 21/30617; H01L 21/30621; H01L 29/2003; H01L 29/66462; H01L 29/7786

(57) ABSTRACT

The present invention realizes a semiconductor device capable of forming a good contact with a 2DEG layer. The semiconductor device includes a recess formed in a partial region of a surface of the barrier layer and having a depth reaching the channel layer, and an electrode formed to cover along the recess. The recess has a first side surface being an exposed surface of the barrier layer and having an angle with respect to a main surface of the substrate, a terrace continuing to the first side surface and being an exposed surface of the channel layer, and a second side surface continuing to the terrace, being an exposed surface of the channel layer, and having an inclination angle smaller than the angle of the first side surface with respect to the main surface of the substrate.

### CROSS-REFERENCE

This application claims priority to Japanese patent application no. 2023-053329 filed on Mar. 29, 2023, the contents of which are fully incorporated herein by reference.

### BACKGROUND OF THE INVENTION

### Technical Field

The present invention relates to a semiconductor device and a method for producing the semiconductor device.

### Background Art

A well-known semiconductor device has a heterojunction structure in which a channel layer made of GaN and a barrier layer made of AlGaN are sequentially deposited, and operates with a two-dimensional electron gas (2DEG) layer formed on a heterojunction interface as a channel layer.

In such a semiconductor device, a recess structure may be provided to ensure a good contact between an electrode and the 2DEG layer (for example, Japanese Patent No. 5329606). In the recess structure, a recess having a depth reaching the channel layer is formed in a partial region of a surface of the barrier layer, a heterojunction interface is exposed on a side surface of the recess, and an electrode is formed along top, side, and bottom surfaces of the recess. Such structure can reduce the contact resistance because the electrode is in contact with the 2DEG layer.

JP-A-2012-99542 and Japanese Patent No. 5625314 disclose a Heterojunction Field Effect Transistor (HFET) having two-step inclined surfaces on a side surface of a recess. The inclination angle of the side surface of the recess is changed at a position where the barrier layer is exposed, and the angle of the upper-step side surface is smaller than the angle of the lower-step side surface. Japanese Patent No. 7057473 discloses the recess structure having a side surface with different inclination angles.

### SUMMARY OF THE INVENTION

The recess is formed by dry etching, which causes etching damage on the recess. This etching damage cannot be eliminated.

The side surface of the recess is inclined so that the actual thickness of the AlGaN layer becomes thin. Thus, the 2DEG concentration is reduced in a vicinity of the recess.

When the electrode is formed in the recess, the electrode needs to be precisely fitted with the steps of the recess to prevent the disconnection of the electrode due to the step or the contactless between the electrode and the 2DEG layer. Therefore, sputtering having superior step coverage is selected as a method for forming an electrode. However, sputtering may damage the semiconductor.

The present invention has been made in view of the above problem, and an object thereof is to provide a semiconductor device capable of forming a good contact with a 2DEG layer and a method for producing the semiconductor device.

One aspect of the present invention is
a semiconductor device including a substrate, a channel layer formed on the substrate and made of Group III nitride semiconductor, and a barrier layer formed on and in contact with the channel layer and made of Group III nitride semiconductor having an Al composition higher than an Al composition of the channel layer, the semiconductor device further including:
a recess formed in a partial region of a surface of the barrier layer and having a depth reaching the channel layer; and
an electrode formed to cover along the recess, in which
the recess has
   a first side surface being an exposed surface of the barrier layer and having an angle with respect to a main surface of the substrate;
   a terrace continuing to the first side surface and being an exposed surface of the channel layer; and
   a second side surface continuing to the terrace, being an exposed surface of the channel layer, and having an inclination angle smaller than the angle of the first side surface with respect to the main surface of the substrate.

The other aspect of the present invention is
a method for producing a semiconductor device including a substrate, a channel layer formed on the substrate and made of Group III nitride semiconductor, and a barrier layer formed on and in contact with the channel layer and made of Group III nitride semiconductor having an Al composition higher than an Al composition of the channel layer, the method including:
forming a first recess by dry etching a predetermined region of a surface of the barrier layer to have a side surface inclined with respect to a main surface of the substrate and a bottom surface deeper than a top surface of the channel layer;
forming a second recess by wet etching a side surface of the first recess with an alkaline solution; and
forming an electrode on the barrier layer to cover the second recess, in which
in forming the second recess,
   a first side surface is formed by the wet etching of the barrier layer to have an angle with respect to the main surface of the substrate, and a top surface of the channel layer is exposed by the wet etching to thereby form a terrace, and
   a second side surface is formed by the wet etching of the channel layer to have an inclination angle smaller than the angle of the first side surface with respect to the main surface of the substrate.

The present invention can achieve high coverage of the electrode for the recess and prevent the disconnection due to a step (hereinafter, referred to as step disconnection) of the electrode. As a result of this, the contact resistance of the electrode can be reduced.

### BRIEF DESCRIPTION OF THE DRAWINGS

FIG. 1 is a cross-sectional view illustrating a structure of a semiconductor device according to a first embodiment, taken perpendicular to a main surface of a substrate;

FIG. 2 is an enlarged cross-sectional view of a recess of the semiconductor device according to the first embodiment;

FIG. 3 is a top view illustrating an electrode pattern;

FIG. 4 is a view illustrating processes for producing the semiconductor device according to the first embodiment;

FIG. 5 is a view illustrating processes for producing the semiconductor device according to the first embodiment;

FIGS. 6A and 6B are views illustrating processes for forming the recess of the semiconductor device according to the first embodiment;

FIG. 7 is a graph comparing contact resistivities;

FIG. 8 is a graph showing distribution of ON resistances of semiconductor devices; and

FIGS. 9A and 9B are cross-sectional SEM images.

### DETAILED DESCRIPTION OF PREFERRED EMBODIMENTS

A semiconductor device including a substrate, a channel layer formed on the substrate and made of Group III nitride semiconductor, a barrier layer formed on and in contact with the channel layer and made of Group III nitride semiconductor having an Al composition higher than an Al composition of the channel layer, the semiconductor device includes a recess formed in a partial region of a surface of the barrier layer and having a depth reaching the channel layer, and an electrode formed to cover along the recess, in which the recess has a first side surface being an exposed surface of the barrier layer and having an angle with respect to a main surface of the substrate, a terrace continuing to the first side surface and being an exposed surface of the channel layer, and a second side surface continuing to the terrace, being an exposed surface of the channel layer, and having an inclination angle smaller than the angle of the first side surface with respect to the main surface of the substrate.

The width of the terrace may be 100 nm or more. This can improve the coverage of the electrode, thereby surely preventing the step disconnection of the electrode.

The first side surface may have an angle of 80° to 90° with respect to the main surface of the substrate. Moreover, the first side surface may be a m-plane of the barrier layer. This can prevent the reduction of 2DEG concentration in the 2DEG layer in a vicinity of the side surface of the recess.

A method for producing a semiconductor device including a substrate, a channel layer formed on the substrate and made of Group III nitride semiconductor, and a barrier layer formed on and in contact with the channel layer and made of Group III nitride semiconductor having an Al composition higher than an Al composition of the channel layer, the method includes: forming a first recess by dry etching a predetermined region of a surface of the barrier layer to have a side surface inclined with respect to a main surface of the substrate and a bottom surface deeper than a top surface of the channel layer, forming a second recess by wet etching a side surface of the first recess with an alkaline solution, and forming an electrode on the barrier layer to cover the second recess. In forming the second recess, a first side surface is formed by the wet etching of the barrier layer to have an angle with the main surface of the substrate, a top surface of the channel layer is exposed by the wet etching to thereby form a terrace, and a second side surface is formed by the wet etching of the channel layer to have an inclination angle smaller than the angle of the first side surface with respect to the main surface of the substrate.

In forming the second recess, a terrace may be formed to have a width of 100 nm or more. This can improve the coverage of the electrode, thereby surely preventing the disconnection of the electrode due to a step.

In forming the second recess, the first side surface of the recess may be formed to have an angle of 80° to 90° with respect to the main surface of the substrate. Moreover, the first side surface of the recess may be formed to be a m-plane. This can prevent the reduction of 2DEG concentration in the 2DEG layer in a vicinity of the side surface of the recess. The alkaline solution may be a Tetramethylammonium Hydroxide (TMAH) solution.

### First Embodiment

### 1. Structure of Semiconductor Device

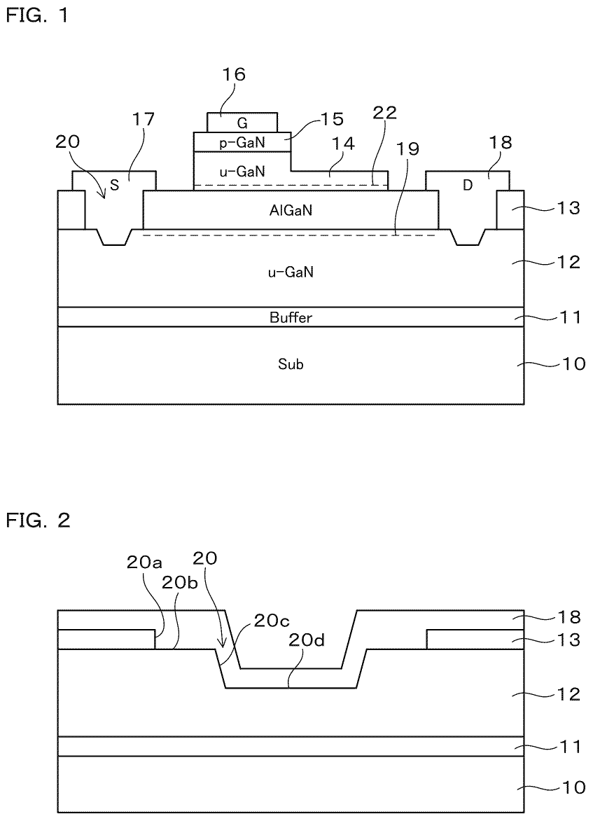

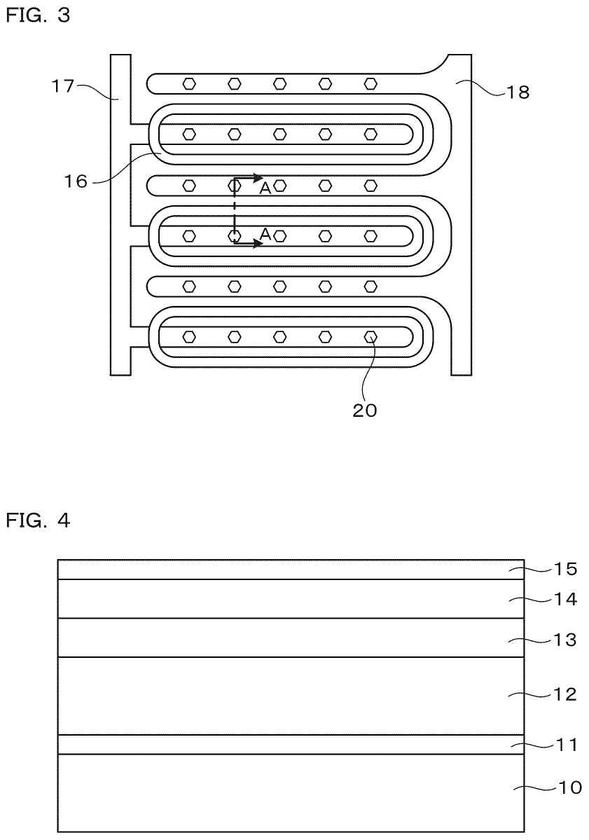

FIG. 1 is a cross-sectional view illustrating a structure of a semiconductor device according to a first embodiment, taken perpendicular to a main surface of a substrate. The semiconductor device according to the first embodiment is a Polarization Super Junction (PSJ) Field Effect Transistor (FET). As shown in FIG. 1, the semiconductor device includes a substrate 10, a buffer layer 11, a channel layer 12, a barrier layer 13, an undoped layer 14, a p-type layer 15, a gate electrode 16, a source electrode 17, and a drain electrode 18. FIG. 2 is an enlarged cross-sectional view of a recess of the semiconductor device according to the first embodiment. FIG. 3 is a top view illustrating electrode patterns. FIG. 1 is also a view taken along the A-A cross section shown in FIG. 3.

The substrate 10 is made of sapphire having a c-plane or a-plane main surface. The thickness of the substrate 10 is, for example, 50 μm to 500 μm.

The channel layer 12 is disposed via the buffer layer 11 on the substrate 10. The channel layer 12 is made of undoped GaN. The buffer layer 11 is made of, for example, low temperature grown AlN or GaN. The thickness of the channel layer 12 is, for example, 300 nm to 5,000 nm.

The barrier layer 13 is disposed on the channel layer 12. The barrier layer 13 is made of undoped AlGaN. The Al composition of the barrier layer 13 is 10% to 50%. The channel layer 12 forms a heterojunction with the barrier layer 13, and a two-dimensional electron gas (2DEG) layer 19 is formed in the channel layer 12 in a vicinity of an interface between the channel layer 12 and the barrier layer 13. The semiconductor device according to the first embodiment operates with this 2DEG layer 19 as a channel. The thickness of the barrier layer 13 is, for example, 20 nm to 150 nm.

The undoped layer 14 is disposed in a partial region on the barrier layer 13 (except for a region for forming the source electrode 17 and the drain electrode 18). The undoped layer 14 is made of undoped GaN. The barrier layer 13 forms a heterojunction with the undoped layer 14, and a two-dimensional hole gas (2DHG) layer 22 is formed in the undoped layer 14 in a vicinity of an interface between the barrier layer 13 and the undoped layer 14. This 2DHG layer 22 does not function as a channel, but flatten the electric field distribution and achieve high breakdown voltage. The thickness of the undoped layer 14 is, for example, 10 nm to 1,000 nm.

The p-type layer 15 is disposed in a partial region closer to the source electrode 17 on the undoped layer 14. The p-type layer 15 is made of p-GaN. The Mg concentration of the p-type layer 15 is, for example, 1×10¹⁷ cm⁻³ to 3×10²⁰ cm⁻³. The thickness of the p-type layer 15 is, for example, 20 nm to 150 nm. The p-type layer 15 may have a two-layer structure of a low-concentration p-type layer and a high-concentration p-type layer.

The gate electrode 16 is disposed on the p-type layer 15. The gate electrode 16 is made of, for example, Ni/Au.

The recess 20 is formed in a region for forming the source electrode 17 and the drain electrode 18 of the surface of the barrier layer 13, and has a depth reaching the channel layer 12. The side surface of the recess 20 has a two-stepped shape consisting of a side surface 20a being an exposed surface of the barrier layer 13, a terrace 20b continuing to the lower end of the side surface 20a and being an exposed surface of the channel layer 12, a side surface 20c continuing to one end of the terrace 20b and being an exposed surface of the channel layer 12, and a bottom surface 20d continuing to the lower end of the side surface 20c, being an exposed surface of the channel layer 12, and being disposed deeper than the top surface of the channel layer 12.

The side surface 20a is a surface perpendicular to a main surface of the barrier layer 13, for example, a m-plane of AlGaN. The side surface 20a may be an a-plane surface other than m-plane. The side surface 20a is not necessarily a surface perpendicular to the main surface of the barrier layer 13 as long as the inclination angle with respect to the main surface of the substrate 10 is larger than the inclination angle of the side surface 20c. However, the side surface 20a is preferably almost perpendicular to the main surface of the barrier layer 13. For example, the side surface 20a preferably has an angle of 80° to 90° with respect to the main surface of the substrate 10, and is most preferably perpendicular to the main surface of the substrate 10. The side surface 20a is a surface exposed by wet etching, and has no etching damage.

The terrace 20b is a top surface of the channel layer 12, and a c-plane of GaN. The terrace 20b is a surface exposed by wet etching, and has no etching damage. The terrace 20b continues perpendicular to the side surface 20a.

The width of the terrace 20b is preferably 100 nm or more. Here, the width of the terrace 20b refers to a width of the terrace 20b in a direction of a shortest straight line connecting the source electrode 17 and the drain electrode 18 in a plan view. When the electrode patterns are as shown in FIG. 3 described later, the width of the terrace 20b refers to a width in a direction intersecting the stripe direction of the stripe-shaped electrodes. When the width of the terrace 20b is set sufficiently wide, to 100 nm or more, the coverage of the source electrode 17 and the drain electrode 18 can be improved for the recess 20, and the source electrode 17 and the drain electrode 18 can be prevented from being disconnected by a step of the recess 20. The width of the terrace 20b is more preferably 140 nm or more.

In addition, the width of the terrace 20b is preferably 1,000 nm or less. This is because the area of the 2DEG layer 19 is reduced due to an increase in the width of the terrace 20b.

The side surface 20c has an angle with respect to a main surface of the channel layer 12. That angle is smaller than the inclination angle of the side surface 20a, for example, 40° to 80° with respect to the main surface of the substrate 10. Since the side surface 20c is inclined, the coverage of the source electrode 17 and the drain electrode 18 for the recess 20 can be further improved. The side surface 20c is a surface exposed by wet etching, and has no etching damage. The side surface 20c continues at an angle to the terrace 20b. The side surface 20c is a surface made by inclining, for example, a m-plane.

The bottom surface 20d is a surface parallel to the main surface of the channel layer 12, and a c-plane of GaN. The bottom surface 20d is a surface disposed at a position deeper than the top surface of the channel layer 12 (at a position on the substrate 10 side), and exposed by dry etching the channel layer 12. The bottom surface 20d continues at an angle to the side surface 20c. A height from the bottom surface 20d to the top surface of the channel layer 12 may be any value, for example, 10 nm or more as long as it is more than 0.

The source electrode 17 and the drain electrode 18 are formed apart from each other in a predetermined region on the barrier layer 13. The source electrode 17 and the drain electrode 18 are also formed to cover the recess 20. That is, the source electrode 17 and the drain electrode 18 are formed to be in contact with the side surface 20a, the terrace 20b, the side surface 20c, and the bottom surface 20d of the recess 20. Therefore, the source electrode 17 and the drain electrode 18 are in contact with the 2DEG layer 19 in a vicinity of an angle part made between the side surface 20a and the terrace 20b of the recess 20. Thus, the contact resistances of the source electrode 17 and the drain electrode 18 are reduced. The source electrode 17 and the drain electrode 18 are made of, for example, Ti/Al/Ti or V/Al/Ti.

Next will be described the plane pattern of the recesses 20 and the electrodes. In a plan view, the source electrode 17 and the drain electrode 18 are formed at designated intervals, and the gate electrode 16 is formed sandwiched between the source electrode 17 and the drain electrode 18.

As shown in FIG. 3, the source electrode 17 and the drain electrode 18 have a comb-line plane pattern. That is, the plane pattern has a stripe part in which long line shaped patterns are arranged at designated intervals in parallel and a part connecting each of the long line shaped patterns. The stripe part of the source electrode 17 and the stripe part of the drain electrode 18 are arranged to be mutually engaged with each other via a gap.

The gate electrode 16 is formed in a ring shaped pattern to surround each of the long line shaped patterns of the source electrode 17.

As shown in FIG. 3, a plurality of recesses 20 are arranged at designated intervals along the line inside each of the long line shaped patterns of the source electrode 17 and the drain electrode 18. The recess 20 has, for example, a regular hexagonal planar shape. This is because the side surface 20a of the recess 20 is a m-plane. Needless to say, the plane shape of the recess is not limited to a regular hexagon. It may be, for example, an equilateral triangle, a square, a rectangle, or a circle.

The diameter of recess 20 may be set to any value as long as it is included in the patterns of the source electrode 17 and the drain electrode 18 in a plan view. In FIG. 3, the diameter of the recess 20 may be smaller than the width of the long line shaped patterns of the source electrode 17 and the drain electrode 18. For example, the width of the long line shaped pattern is 20 μm, and the diameter of the recess 20 is 5 μm.

The plane pattern of the gate electrode 16, the source electrode 17, and the drain electrode 18 is merely an example, and are not limited to the pattern shown in FIG. 3.

### 2. Operation of Semiconductor Device

In the semiconductor device according to the first embodiment is a normally-on device, in which current flows via the 2DEG layer 19 from the drain electrode 18 to the source electrode 17 when no voltage is applied to the gate electrode 16. When a voltage not more than the threshold voltage (negative voltage) is applied to the gate electrode 16, current from the drain electrode 18 to the source electrode 17 is turned off.

When a voltage not more than the threshold voltage (negative voltage) is applied to the gate electrode 16, holes are extracted from the 2DHG layer 22 and disappear. Accompanying this, electrons disappear from the 2DEG layer 19 below the undoped layer 14. Thus, the lower region of the undoped layer 14 is entirely depleted so that the electric field is made constant. Thereby, the electric field applied from the drain electrode 18 to the gate electrode 16 can be uniformly distributed, and there is no electric field concentrated region. As a result, extremely high breakdown voltage can be achieved.

When a voltage more than the threshold voltage to the gate electrode 16, current flows from the drain electrode 18 to the source electrode 17 to turn on the device. At this time, current flows from the drain electrode 18 to the 2DEG layer 19 through the surface of the barrier layer 13 and the side surface 20a of the recess 20. Then, current flows from the 2DEG layer 19 to the source electrode 17 through the surface of the barrier layer 13 and the side surface 20a of the recess 20.

Since the recess 20 has a structure shown in FIG. 2, the source electrode 17 and the drain electrode 18 can form a good contact with the 2DEG layer 19. The details are as follows.

The side surface 20a of the recess 20 is perpendicular to the main surface of the substrate 10. Therefore, the substantial thickness of the barrier layer 13 is not reduced. When the side surface 20a is inclined, strain is relaxed and the substantial thickness of the barrier layer 13 is reduced. Since the substantial thickness of the barrier layer 13 is not reduced, the 2DEG concentration of the 2DEG layer 19 can be prevented from being reduced in a vicinity of the side surface of the recess 20. As a result, the source electrode 17 and the drain electrode 18 can form a good contact with the 2DEG layer 19.

The side surface of the recess 20 includes a side surface 20a perpendicular to the main surface of the substrate 10, a terrace 20b being a top surface of the channel layer 12, a side surface 20c inclined with respect to the main surface of the substrate 10, and has two steps. Such a step structure can improve the coverage of the source electrode 17 and the drain electrode 18 for the recess 20, and prevent the step disconnection of the source electrode 17 and the drain electrode 18. As a result, the source electrode 17 and the drain electrode 18 are closely adhered to an angle part made between the terrace 20b and the side surface 20c, thereby forming a good contact with the 2DEG layer 19 in a vicinity of the angle part.

The side surface 20a, the terrace 20b, and the side surface 20c of the recess 20 are a surface exposed by wet etching after dry etching although the details will be described in 3. Method for Producing Semiconductor Device. Therefore, these surfaces have no etching damage. The source electrode 17 and the drain electrode 18 are in contact with the surfaces without etching damage, thereby reducing the contact resistance.

Form the above, in the semiconductor device according to the first embodiment, the recess 20 is formed in a shape having a side surface 20a, a terrace 20b, a side surface 20c, and a bottom surface 20d as shown in FIG. 2. This can achieve high coverage of the source electrode 17 and the drain electrode 18 for the recess 20, and can prevent the step disconnection of the source electrode 17 and the drain electrode 18. Thus, the contact resistance of the source electrode 17 and the drain electrode 18 can be reduced.

### 3. Method for Producing Semiconductor Device

Next will be described the method for producing the semiconductor device according to the first embodiment, with reference to the drawings.

Firstly, a channel layer 12, a barrier layer 13, an undoped layer 14, and a p-type layer 15 are sequentially deposited via a buffer layer 11 on a substrate 10 through Metal Organic Chemical Vapor Deposition (MOCVD) (refer to FIG. 4). The following raw material gases are employed for MOCVD: Tri-Methyl Gallium (TMG) as a Ga source; Tri-Methyl Aluminum (TMA) as an Al source; ammonia as a nitrogen source; and hydrogen and nitrogen as carrier gases.

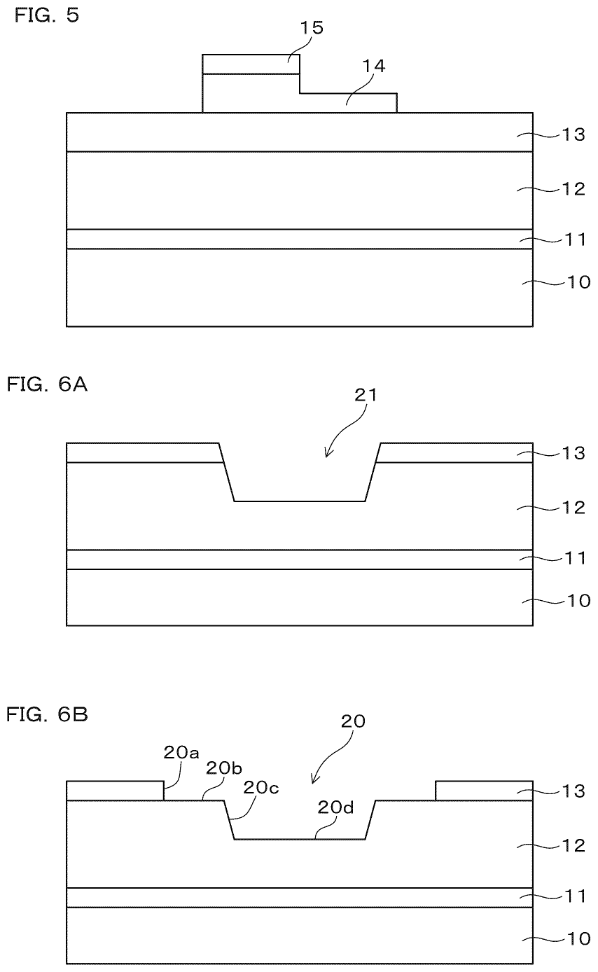

Subsequently, a predetermined region of the p-type layer 15 is removed by dry etching to thereby expose the undoped layer 14. Then, regions for forming a source electrode 17 and a drain electrode 18 of the thus exposed undoped layer 14 are removed by dry etching to thereby expose the barrier layer 13 (refer to FIG. 5).

Next, a recess 21 is formed by dry etching a predetermined region of the barrier layer 13 (refer to FIG. 6A). Here, the etching conditions are set to make a side surface of the recess 21 inclined. The inclination angle of the side surface of the recess 21 is, for example, 30° to 70° with respect to a main surface of the substrate 10. In addition, the recess 21 is formed deeper than the top surface of the channel layer 12. Such dry etching causes etching damage on the side surface or the bottom surface of the recess 21.

Subsequently, the side surface of the recess 21 is wet etched using a tetramethylammonium hydroxide (TMAH) solution. The concentration of the TMAH solution is, for example, 15 wt % to 25 wt %. The temperature of the TMAH solution is, for example, 60° C. to 90° C. As long as the concentration or the temperature is within this range, the difference in etching speed between the barrier layer 13 and the channel layer 12 is proper, thereby facilitating the formation of the recess 20.

The etching time is, for example, 10 to 30 minutes. When the etching time is shorter than 10 minutes, the width of a terrace 20b is not sufficiently increased, the coverage of the source electrode 17 and the drain electrode 18 may be reduced or the step disconnection of the electrodes may occur. When the etching time is longer than 30 minutes, the channel layer 12 is over etched to expose a m-plane surface, and thus a side surface 20c becomes perpendicular. As a result, the coverage of the source electrode 17 and the drain electrode 18 may be reduced or the step disconnection of the electrodes may occur.

In wet etching Group III nitride semiconductor using the TMAH solution, the side surface of the recess 20 is etched because it is a surface other than a c-plane. However, the top surface of the barrier layer 13, the exposed top surface of the channel layer 12, and the bottom surface of the recess 20 are not etched because they are a c-plane. In addition, the higher the Al composition, the higher the etching speed. As etching proceeds, the m-plane is exposed, and the etching propagates with the m-plane fixed.

Thus, a recess 20 having a side surface 20a, the terrace 20b, a side surface 20c, and a bottom surface 20d, is formed by wet etching the recess 21 (refer to FIG. 6B). The details are as follows.

Of the side surface of the recess 21, a region for exposing the barrier layer 13 is laterally etched at a high speed, and a region for exposing the channel layer 12 is etched at a lower speed than the etching speed of the region for exposing the barrier layer 13. This is because the Al composition of the barrier layer 13 is higher than the Al composition of the channel layer 12. The top surface of the channel layer 12 is exposed by this etching. The thus-exposed top surface of the channel layer 12 is not etched because it is a c-plane. Thus, the terrace 20b of the recess 20 is formed. The terrace 20b has no etching damage because it is not exposed in forming the recess 21.

As the etching of this barrier layer 13 proceeds, a m-plane of the barrier layer 13 is exposed so that the side surface 20a of the recess 20 is formed perpendicular to the main surface of the barrier layer 13. In addition, etching damage on the side surface 20a is removed by etching the barrier layer 13.

The region for exposing the channel layer 12 Of the side surfaces of the recess 21 is GAN with an Al composition of 0, lower than the Al composition of the barrier layer 13. Therefore, the etching speed is lower than the etching speed of the region for exposing the barrier layer 13. As a result, etching does not proceed to such extent that the side surface of the channel layer 12 becomes perpendicular, and the side surface of the channel layer 12 is inclined. The inclined side surface of the channel layer 12 is the side surface 20c of the recess 20. The inclination angle of the side surface 20c is equal to or more than the inclination angle of the side surface of the recess 21. In addition, etching damage on the side surface 20c is removed by etching the channel layer 12.

The bottom surface of the recess 21 is not etched because it is a c-plane, and remains as the bottom surface 20d of the recess 20. In this way, the recess 20 having the side surface 20a, the terrace 20b, the side surface 20c, and the bottom surface 20d is formed.

In wet etching, an alkaline solution such as KOH and NaOH other than TMAH may be employed. Solvent is not limited to an aqueous solvent.

Next, a source electrode 17 and a drain electrode 18 are formed on a predetermined region on the barrier layer 13. The source electrode 17 and the drain electrode 18 are formed to cover the recess 20. When the source electrode 17 and the drain electrode 18 are made of the same material, they may be formed at the same time.

Here, the recess 20 has the terrace 20b being an exposed surface of the channel layer 12, and the side surface 20c of the recess 20 is inclined. Therefore, the source electrode 17 and the drain electrode 18 can be formed to precisely cover along the step of the recess 20, thereby preventing the step disconnection. Particularly, the source electrode 17 and the drain electrode 18 can be closely adhered to the 2DEG layer 19 exposed in a vicinity of an angle part made between the terrace 20b and the side surface 20c.

Vapor deposition or sputtering may be used for forming the source electrode 17 and the drain electrode 18. Electron beam-physical (EB) vapor deposition is particularly preferred. Conventionally, sputtering having high coverage has been employed to cover the recess without causing a step disconnection of the source electrode 17 and the drain electrode 18. However, sputtering caused damage on the semiconductor layer in some cases. The recess 20 of the first embodiment achieves high coverage of the source electrode 17 and drain electrode 18 have high coverage because of its shape. Thus, the step disconnection of the source electrode 17 and the drain electrode 18 can be prevented even if they are formed through vapor deposition.

The contact resistance of the source electrode 17 and the drain electrode 18 can be reduced because they are in contact with the side surface 20a, the terrace 20b, and the side surface 20c of the recess 20, which have no etching damage.

Subsequently, heat treatment is performed to reduce the contact resistance of the source electrode 17 and the drain electrode 18. The heat treatment conditions are, for example, 500° C. to 700° C., 60 to 600 seconds, and a nitrogen atmosphere.

Next, a gate electrode 16 is formed on the p-type layer 15 through vapor deposition or other method. A gate electrode 16 is formed at first, and subsequently, a recess 20, a source electrode 17 and a drain electrode 18 may be formed. In this way, the semiconductor device according to the first embodiment is produced.

### 4. Experimental Results

A semiconductor device according to the first embodiment having a recess 20 formed in the following steps, was prepared as a sample A. Firstly, a recess 21 having a depth reaching a channel layer 12 was formed by dry etching. After that, wet etching was performed using a TMAH solution with a concentration of 2.3 wt %, at 50° C. for 20 minutes. Thus, a recess 20 having a terrace 20b with a width of 40 nm was formed. Then, an electrode was formed over on a top surface, a side surface, and a bottom surface of the recess 20. The electrode was made of Ti/Al/Ti, and the alloy temperature was 600° C.

Moreover, a semiconductor device according to the first embodiment having a recess 20 formed in the following steps, was prepared as a sample B. In preparing the sample B, the steps of wet etching after the formation of the recess 21 was changed as follows. Except for that, the sample B was prepared in the same way as in preparing the sample A. Wet etching was performed using a TMAH solution with a concentration of 22 wt %, at 85° C. for 20 minutes. Thus, a recess 20 having a terrace 20b with a width of 140 nm was formed.

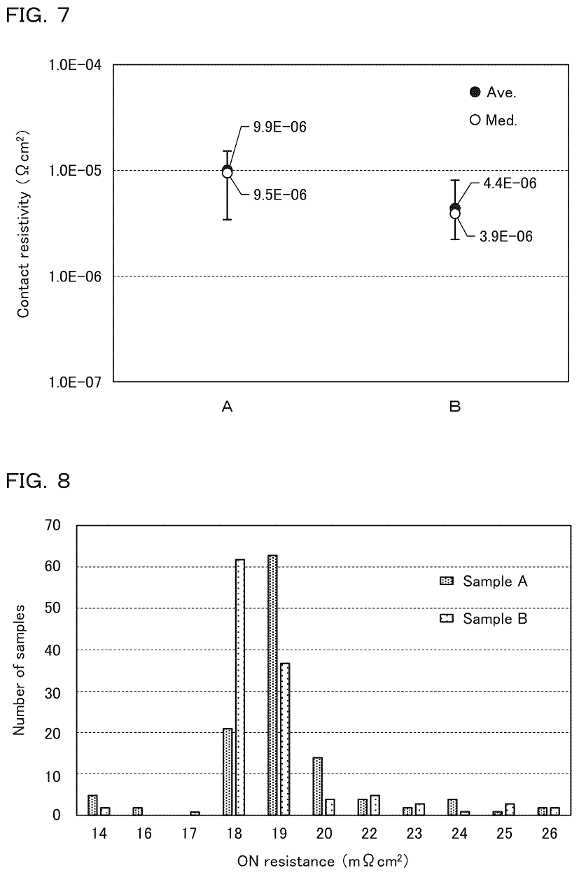

FIG. 7 is a graph showing the comparison results of the contact resistances measured by TLM patterns of samples A and B. As shown in FIG. 7, both an average value and a median value of the contact resistivities were lower in the sample B than in the sample A.

A plurality of semiconductor devices according to the first embodiment having a recess 20 as samples A and B were prepared, and the ON resistance was measured in each of the semiconductor devices. FIG. 8 is a graph showing distribution of ON resistances of the semiconductor devices. As shown in FIG. 8, it was found that the most frequent value of the ON resistance of the sample B was one mΩcm² lower than the most frequent value of the ON resistance of the sample A.

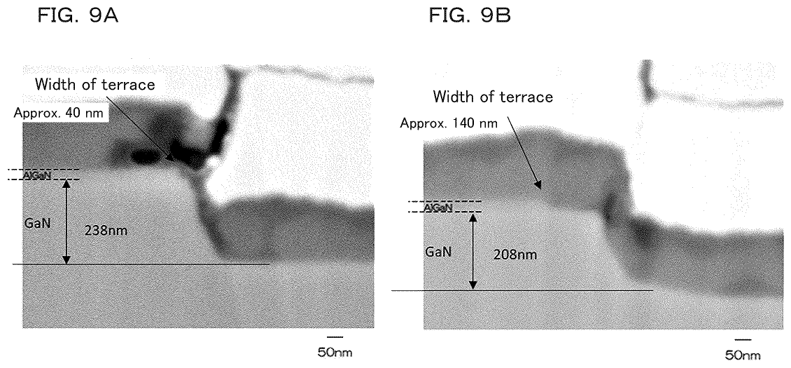

FIGS. 9A and 9B are cross-sectional SEM images taken from the cross sections of the recesses in the samples A and B. As shown in FIG. 9A, the step disconnection of the electrode was observed in the sample A. On the contrary, as shown in FIG. 9B, the step disconnection of the electrode was not observed in the sample B.

As is clear from FIGS. 7 to 9A and 9B, when the width of the terrace 20b is increased in the recess 20, the coverage of the electrode for the recess 20 is improved, thereby preventing the step disconnection of the electrode. Moreover, by improving the coverage and preventing the step disconnection, the contact resistivity of the electrode can be reduced, and the ON resistance can be reduced.

### 5. Variations

The present invention is not limited to the semiconductor device according to the first embodiment. The present invention is applicable to any semiconductor device having a structure of a channel layer made of Group III nitride semiconductor, a barrier layer made of Group III nitride semiconductor having an Al composition higher than the Al composition of the channel layer, and an electrode formed in contact with a 2DEG layer by a recess. For example, the present invention is applicable to a HFET and others.

What is claimed is:

1. A semiconductor device including a substrate, a channel layer formed on the substrate and made of Group III nitride semiconductor, and a barrier layer formed on and in contact with the channel layer and made of Group III nitride semiconductor having an Al composition higher than an Al composition of the channel layer, the semiconductor device further comprising:
a recess formed in a partial region of a surface of the barrier layer and having a depth reaching the channel layer; and
an electrode formed to cover along the recess, wherein
the recess has
a first side surface being an exposed surface of the barrier layer and having an angle with respect to a main surface of the substrate;
a terrace continuing to the first side surface and being an exposed surface of the channel layer; and
a second side surface continuing to the terrace, being an exposed surface of the channel layer, and having an inclination angle smaller than the angle of the first side surface with respect to the main surface of the substrate.

2. The semiconductor device according to claim 1, wherein a width of the terrace is 100 nm or more.

3. The semiconductor device according to claim 1, wherein the first side surface has an angle of 80° to 90° with respect to the main surface of the substrate.

4. The semiconductor device according to claim 1, wherein the first side surface is a m-plane of the barrier layer.

5. A method for producing the semiconductor device including a substrate, a channel layer formed on the substrate and made of Group III nitride semiconductor, and a barrier layer formed on and in contact with the channel layer and made of Group III nitride semiconductor having an Al composition higher than an Al composition of the channel layer, the method comprising:
forming a first recess by dry etching a predetermined region of a surface of the barrier layer to have a side surface inclined with respect to a main surface of the substrate and a bottom surface deeper than a top surface of the channel layer;
forming a second recess by wet etching a side surface of the first recess with an alkaline solution; and
forming an electrode on the barrier layer to cover the second recess, wherein
in forming the second recess,
a first side surface is formed by the wet etching of the barrier layer to have an angle with respect to the main surface of the substrate, and a top surface of the channel layer is exposed by the wet etching to thereby form a terrace, and
a second side surface is formed by the wet etching of the channel layer to have an inclination angle smaller than the angle of the first side surface with respect to the main surface of the substrate.

6. The method for producing the semiconductor device according to claim 5, wherein the terrace is formed to have a width of 100 nm or more in forming the second recess.

7. The method for producing the semiconductor device according to claim 5, wherein the first side surface is formed to have an angle of 80° to 90° with respect to the main surface of the substrate in forming the second recess.

8. The method for producing the semiconductor device according to claim 5, wherein the first side surface is formed to be a m-plane in forming the second recess.

9. The method for producing the semiconductor device according to claim 5, wherein the alkaline solution is a TMAH solution.
